(19) United States
(12) Patent Application Publication
(10) Pub. No.: US 2023/0024409 A1
(43) Pub. Date: Jan. 26, 2023

(54) ACOUSTIC NOISE SUPPRESSING HEAT EXCHANGERS

(71) Applicant: Intel Corporation, Santa Clara, CA (US)

(72) Inventors: Smit KAPILA, Bangalore (IN); Prakash Kurma RAJU, Bangalore (IN); Abhishek SRIVASTAV, Bangalore KA (IN); Prasanna PICHUMANI, Bangalore KA (IN); Raghavendra Subramanya Setty KANIVIHALLI, Bangalore (IN)

(21) Appl. No.: 17/903,278

(22) Filed: Sep. 6, 2022

(51) Int. Cl. H05K 7/20; G06F 1/20; G10K 11/16

(52) U.S. Cl. CPC H05K 7/20154; G06F 1/206; G10K 11/161; H05K 7/2039

(57) ABSTRACT

A noise suppressing heat exchanger (also referred to as heat sink) includes a plurality of heat dissipating fins formed with baffles. The baffles suppress noise from a fan by slowing air flow and creating internal reflections within the heat exchanger that reflect noise away from the air flow path, absorbing sound energy and potentially setting up standing waves which dissipate noise via destructive interference. Other embodiments may be described and/or claimed.

### TECHNICAL FIELD

Disclosed embodiments are directed to noise mitigation, and specifically, for heat exchangers (also referred to as heat sinks) configured to reduce noise generated by a cooling fan while maintaining effective heat dissipation.

### BACKGROUND

Most computing devices, despite advances in power management strategies and die size, still generate significant amounts of heat. High performance processors, Systems on Chips (SoCs), and graphics processors may each radiate over 100 Watts of heat. Such significant heat energy, if not properly dissipated, could damage the processor and/or require severe throttling of processor speed to keep die temperatures at an acceptable level. Furthermore, a typical computing device may have multiple components that generate heat besides the processor, such as graphics processors, memory controllers, and supporting circuitry, to name a few examples. Long-term, excessive heat can shorten device lifespan by causing premature component failure, and, in the case of portable and mobile devices, may make the device uncomfortably hot in use. Accordingly, a variety of approaches to absorb and dissipate heat away from a computing device’s processor and supporting chips have been developed to allow a computing device to achieve its peak rated performance while keeping components below rated maximum temperatures.

The background description provided herein is for the purpose of generally presenting the context of the disclosure. Unless otherwise indicated herein, the materials described in this section are not prior art to the claims in this application and are not admitted to be prior art by inclusion in this section.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a perspective view of an example heat exchanger with noise suppressing baffles, according to various embodiments.

FIG. 1B illustrates the example heat exchanger of FIG. 1A with the top plate removed, illustrating the baffle configuration, according to various embodiments.

FIG. 1C is a side elevation view of the example heat exchanger of FIG. 1A, illustrating the arrangement of air channels and baffles, according to various embodiments.

FIG. 2A is a perspective view of a second example heat exchanger with a different configuration of noise suppressing baffles, according to various embodiments.

FIG. 2B illustrates the example heat exchanger of FIG. 2A with the top plate in place, according to various embodiments.

FIG. 3 is a perspective view of a third example heat exchanger with another possible configuration of noise suppressing baffles, according to various embodiments.

FIG. 4 is a block diagram of an example computing device that may employ one of the example noise suppressing heat exchangers illustrated in FIG. 1A-FIG. 3, according to various embodiments.

FIG. 5 is a process flow of an example method for fabricating a noise-suppressing heat exchanger, according to various embodiments.

### DETAILED DESCRIPTION

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

Computer devices have long employed heat exchangers to remove and dissipate heat generated by processors and other electronic components. As is understood, the heat exchanger acts to conduct heat away from a component coupled to the heat exchanger, and provides a relatively large surface area with which to radiate absorbed heat into the surrounding environment. Heat exchangers are typically deployed on a vast array of computer and electronic devices, from large servers employed in data centers, to desktop computers, to laptops, to mobile devices, and even some embedded systems. While heat exchangers can vary in their design depending upon the particular requirements of their use, most heat exchangers employ one or more fin-like structures that are formed on a plate (often referred to as a cold plate), to increase the surface area of the heat exchanger for more effective dissipation of heat into the surrounding environment.

The heat exchanger is typically coupled to the heat source desired to be cooled so that heat can be readily transferred into the heat exchanger. This coupling may be via direct contact, such as by placing the cold plate on the component package. Alternatively or additionally, a heat pipe or similar heat-conductive structure may be used to thermally connect a heat exchanger with a component to be cooled, particularly where the component layout and/or case geometry do not allow for directly placing the heat exchanger upon the component. In some implementations, a thermally conductive paste or grease may be applied to the interface of the cold plate and component package or heat pipe to more efficiently transfer heat into the heat exchanger.

Regardless of how the heat exchanger is arranged with respect to its coupled component(s), the heat exchanger must be capable of dissipating sufficient heat to keep the component(s) below its/their maximum temperature rating(s). Where a heat exchanger dissipates heat via radiation, the heat exchanger needs to be of sufficient thermal mass and/or provide sufficient surface area such that the heat produced by the component(s) can be dissipated at least as quickly as the component(s) generate(s) the heat. For high-performance processors, this may necessitate a relatively large heat exchanger, which in turn increases the overall weight and size of the computer device, as well as potentially increases costs. Where the computer device is a laptop or mobile device, such an approach may not be feasible due to device size constraints. In such scenarios, convection cooling, where air is forcibly circulated around the heat exchanger fins, can allow a significantly smaller heat exchanger to dissipate sufficient heat, thereby allowing a laptop to employ relatively high-performance components.

The effectiveness of convection cooling is at least partially dependent upon the speed and mass of the air flow through the heat exchanger. These two factors are related: for a given heat exchanger, a greater speed allows a greater mass of air to flow through the heat exchanger, which in turn hastens removal of heat from the heat exchanger. Air flow can be induced through a heat exchanger either by natural convection, e.g. heating one side of a path can induce air movement similar to a chimney, or via a fan. The fan is typically sized to move sufficient air across the heat exchanger to keep the component within its operating temperature range when at maximum performance. Employing a fan that can vary its speed can allow air flow to be adjusted based on the amount of heat a given device is generating. As the device’s performance increases, the amount of heat it generates may increase, and the fan can correspondingly be sped up in response to increase heat dissipation; similarly, the fan can be slowed, or even stopped, when the component is idling and so producing relatively little heat.

The use of a fan to provide convection current can cause an undesirable side-effect of increased noise. As a fan accelerates, its noise profile increases due to increased air flow through the heat exchanger and the fan blades, and also due to noise inherent in the fan’s motor. Employing a larger fan can somewhat mitigate this problem, as a larger fan can typically spin at a lower speed compared to a smaller fan to move a given volume of air. However, in laptops and mobile devices, space is at a premium, and so using larger fans may not be feasible. As a result, laptops and other mobile devices typically use smaller fans spinning at higher speeds. Furthermore, some laptop and mobile device designers may intentionally throttle device performance to avoid having to run the fan at a speed that would result in an unacceptably high noise profile. This tradeoff can be prevalent in small form factor devices such as ultrabooks, where a lightweight and quiet device is provided at the expense of raw processing power.

Disclosed embodiments address the foregoing limitations by providing a heat exchanger that includes noise suppressing baffles. Baffles have been employed in other applications, e.g. suppressors for firearms, to reflect and cancel noise energy. In embodiments, the baffles act to slow air flow and reflect noise energy so that it is suppressed. The baffles also typically result in an increase in fin surface area, which at least partially compensates for the reduction in heat transfer from the decreased air flow. Consequently, system fans can be run at higher speeds to provide greater cooling while still achieving an acceptable noise profile.

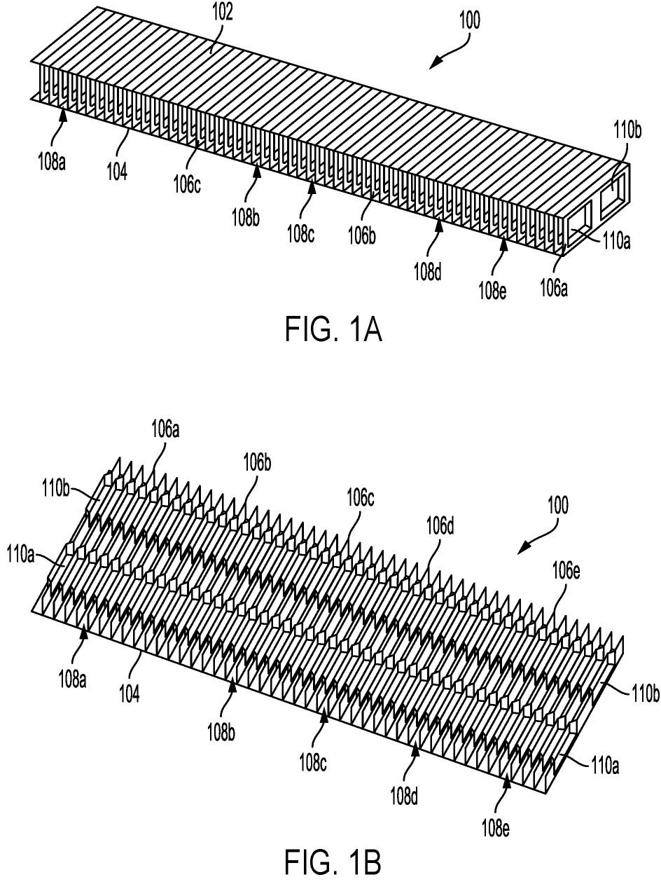

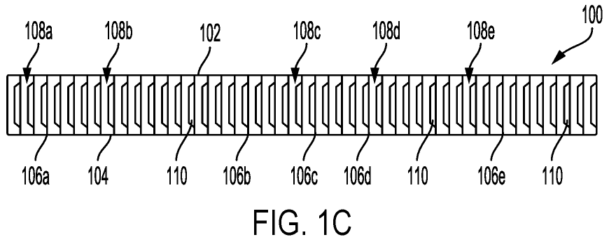

FIGS. 1A-1C illustrate an example noise-suppressing heat exchanger 100, according to some embodiments. Heat exchanger 100 includes a top plate 102 and a bottom plate 104. Between the top plate 102 and bottom plate 104 are disposed a plurality of fins 106a to 106e (generically or collectively, fin 106), which are attached to the top plate 102 and bottom plate 104 to form a corresponding plurality of air channels 108a to 108e (generically or collectively, air channel 108). Note that, in the interest of readability and conserving space, only a few fins 106 and air channels 108 are noted. The reader should understand that fin 106 and air channel 108 can refer to any fin or air channel, regardless of whether labeled.

Top plate 102 and/or bottom plate 104, in embodiments, may be fabricated from a heat conductive material, such as copper or aluminum. Any other material structurally suitable for manufacturing the heat exchanger 100 that is sufficiently heat conductive may be used. Depending upon the needs of a given embodiment, only one of the top plate 102 or bottom plate 104 may be thermally conductive, e.g. when one of the plates is proximate to a heat sensitive structure, or both may be thermally conductive. In embodiments, the top plate 102 and/or bottom plate 104 may act as a cold plate to receive contact either with a component or components to be cooled, or an end of a heat pipe that may be conducting heat away from a more distally located component. The top plate 102 and/or bottom plate 104 may be interfaced with the component(s) or heat pipe by direct contact and/or with the addition of a thermally conductive compound, such as thermal paste. The top plate 102 and/or bottom plate 104 thus serves to remove heat from the contacted structure, and conduct the heat to the fins 106 for dissipation.

It should be understood that, where both top plate 102 and bottom plate 104 are formed from heat conductive material, either side could be used as a cold plate to interface with a component or heat pipe. In other embodiments, both sides could potentially be used as cold plates, thereby allowing the heat exchanger 100 to dissipate heat from multiple components in different locations. For example, bottom plate 104 could be positioned directly on a component, and a plate from a heat pipe could be positioned on the top plate 102, thereby allowing heat exchanger 100 to absorb and dissipate heat from both the component in contact with bottom plate 104 and any components conducting heat through the heat pipe to top plate 102.

Fins 106, in embodiments, may be fabricated from a heat conductive or heat dissipating material, such as copper or aluminum. Any other material structurally suitable for manufacturing the heat exchanger 100 that provides sufficient heat dissipation may be employed. Each of the fins 106 is coupled to the top plate 102 and the bottom plate 104 such that heat in the top plate 102 and/or bottom plate 104 is conducted to each of the fins 106 for dissipation into the air channels 108. In some embodiments, the fins 106 are soldered, welded, or brazed to the top plate 102 and/or bottom plate 104. In other embodiments, the fins 106 may be mechanically attached to the top plate 102 and bottom plate 104, such as via one or more fasteners. In still other embodiments, the fins 106 may be formed as part of the top plate 102, bottom plate 104, or both, such as by machining or extruding; in such embodiments, the top plate 102, bottom plate 104, and fins 106 may comprise a continuous structure.

Each of the fins 106 is positioned relative to its neighbors to form a plurality of air channels 108. The air channels 108 are oriented and spaced so that a fan (not shown) can pass air through the channels 108, whereby the air will absorb heat radiating from the fins 106 and carry it away. Each air channel 108 runs the width of the heat exchanger 100, from one edge to the other. In this orientation, a fan may be placed adjacent to one of the edges that opens into the air channels 108, so that the fan may push air into the air channels 108.

Each of the fins 106, in the depicted embodiment, includes a baffle 110a and 110b (collectively or generically, baffle 110) formed into it. In the depicted embodiment, each baffle 110 is formed as a roughly rectangular protrusion into the side of its corresponding fin 106. As can be seen in FIGS. 1B and 1C, each baffle 110 protrudes into an adjacent air channel 108, so that it impinges into the air flow through the channel 108 when a fan is running. This protrusion can be clearly seen in FIG. 1C, where each baffle 110 extends a short distance into each corresponding air channel 108. The formation of each baffle 110, as seen, creates a corresponding depression on the opposite side of its fin 106.

When the fins 106 are positioned so that the baffles 110 in each fin are all oriented in the same direction, as in the embodiment depicted FIGS. 1B and 1C, the baffles 110 cause air flow in each air channel 108 to deviate around each baffle 110, and potentially past a corresponding depression. Thus, air no longer travels a straight path through each air channel 108, but deviates several times. This deviation slows down the air flow and helps to dissipate sound energy traveling through each air channel. Furthermore, the baffles 110, by impinging upon the air flow, act to reflect at least some of the sound carried from the fan by air entering the heat exchanger 100. This reflected sound is trapped within the heat exchanger 100 rather than being emitted, thereby reducing fan noise. The edges of each baffle 110, which is essentially a rectangular depression with somewhat beveled or chamfered edges, can also reflect sound energy at an angle towards adjacent fins 106. The reflections can set up standing waves within each air channel 108 that helps to further cancel out fan noise via destructive interference.

At least some of the sound reduction realized by baffles 110 is caused by the slowing of air velocity due to the baffles 110 impinging within each air channel 108. This slowing of air velocity can adversely affect heat dissipation, which is enhanced by faster air flow. However, this adverse effect of slowing is roughly compensated by the increased surface area on each fin 106 created by each baffle 110. Accordingly, the net cooling is essentially unchanged over existing non-baffled designs, but with a reduction in emitted fan noise. For example, one possible embodiment realized a reduction in airflow from 1.1 CFM to 1 CFM, but with an increased surface area of 11,772 mm² compared to 10,309 mm² for a comparable existing design. This resulted in a reduction of emitted noise from 30 dBA to 27.5 dBA, with no significant change to effective cooling of the attached component.

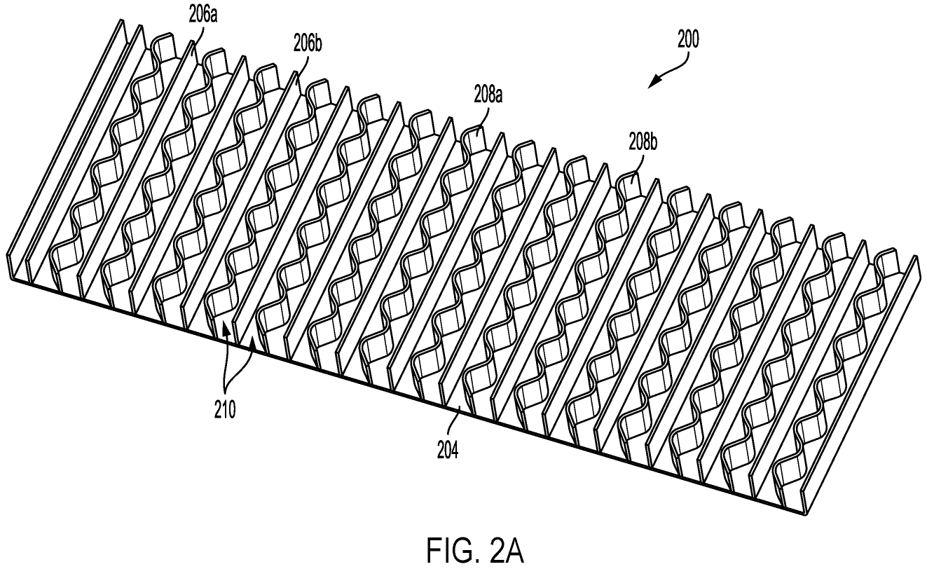

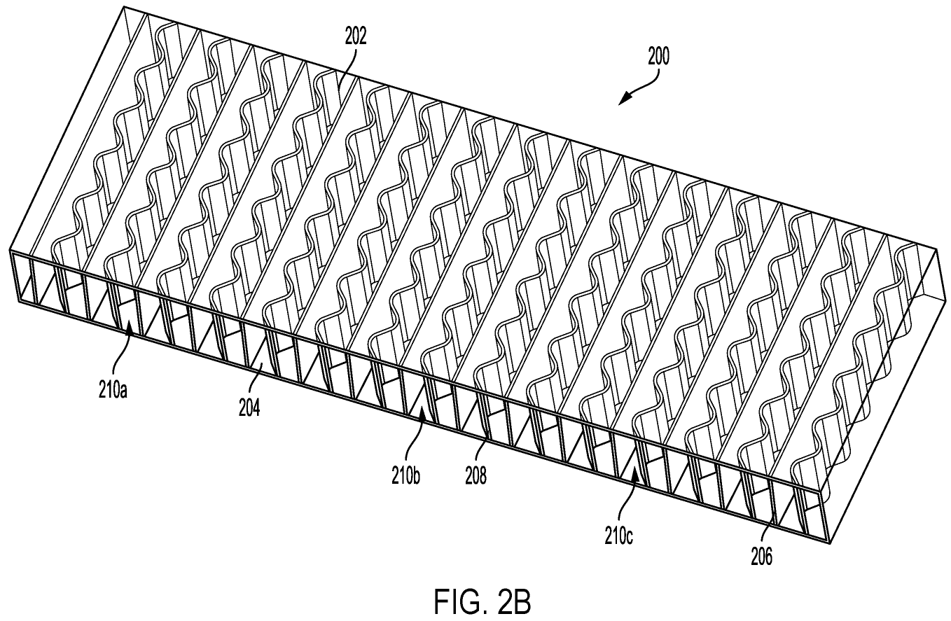

FIGS. 2A and 2B illustrate a second example heat exchanger 200, according to other possible embodiments. As with heat exchanger 100 (FIGS. 1A-1C), heat exchanger 200 includes a top plate 202, and a bottom plate 204, similar to the top plate 102 and bottom plate 104 of heat exchanger 100. Heat exchanger 200 includes two pluralities of fins, the first plurality illustrated by fins 206a and 206b (collectively or generically, fins 206), and the second plurality illustrated by fins 208a and 208b (collectively or generically, fins 208). As with heat exchanger 100, both sets of fins 206 and 208 are disposed between top plate 202 and bottom plate 204 to form a plurality of air channels 210a - 210c (collectively or generically, air channels 210).

In contrast to heat exchanger 100 where all fins 106 included two baffles 110, only the fins 208 are formed with baffles, while fins 206 remain straight. As can be seen in FIG. 2A, the fins 208 are formed into baffles by forming each into a continuous sinusoidal or angular pattern. Consequently, each air channel 210 repeatedly narrows and widens, essentially forming a series of expansion chambers. As with baffles 110, the constrictions cause the air flow to slow, and the expansion chambers act to repeatedly dissipate sound energy emitted from the fan (not shown). Furthermore, as can be seen, each fin 206 is formed into a series of opposing angles that act to reflect sound away from the path of each air channel 210, and towards each other. These opposing angles can set up standing waves and destructive interference, further contributing to the sound reduction effects of the baffles.

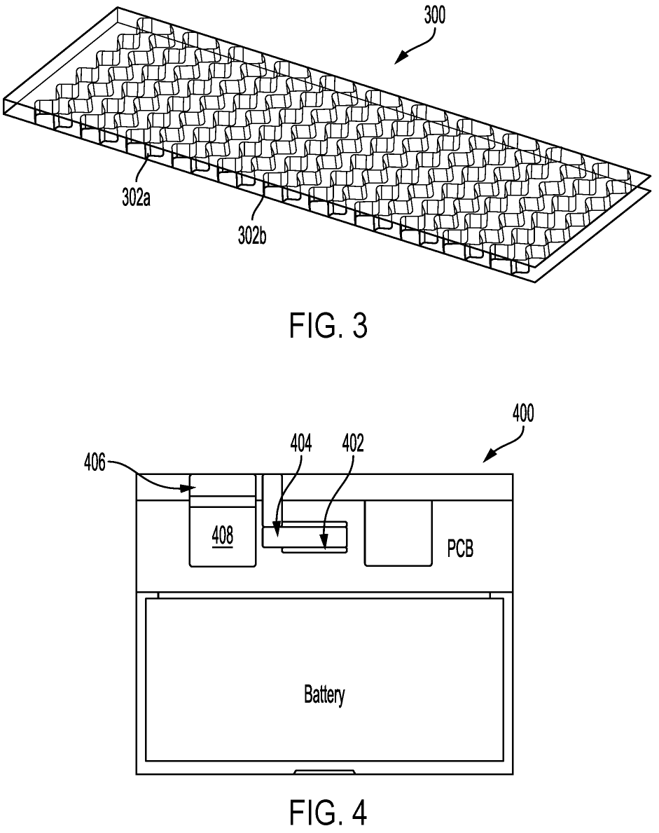

FIG. 3 illustrates a third example heat exchanger 300, according to some possible embodiments. Heat exchanger 300 includes fins 302a and 302b (collectively or generically, fins 302) that are formed into a continuous sinusoidal or angular pattern, similar to fins 208 of heat exchanger 200 (FIGS. 2A and 2B). In contrast to heat exchanger 200, there are no interleaved fins that are straight. Rather, each fin 208 is formed into a series of baffles, with each adjacent fin offset slightly so that each air channel is formed into a roughly continuous width, but that continuously turns. Air is accordingly required to repeatedly change directions as it travels along each air channel, with the continuous turns acting to slow the air flow, dissipate sound energy, and reflect sound energy back within the heat exchanger 300 via destructive interference. Heat exchanger 300 is otherwise identical in construction to heat exchangers 100 (FIGS. 1A-1C) and 200.

A person skilled in the art will further recognize that other possible embodiments of baffles are possible beyond the three example heat exchangers discussed herein. Any heat exchanger with baffles in any configuration that serve to slow air flow through channels and dissipate sound energy are keeping within the scope of this disclosure. Furthermore, some embodiments may combine different types of baffles, e.g. some heat exchangers may have several sets of fins, some with depressions or protrusions, some formed sinusoidally or with angles, and/or some with no baffles, possibly in an interleaved fashion. Still others may have some fins with multiple baffle types, such as formed into a sinusoidal shape or angular shape, with one or more protrusions also formed into the fin. Still others may arrange a plurality of fins that are discontinuous or do not span the entire length of the top plate and bottom plate, and may be angled. These examples are not intended to be limiting, but illustrative of just some of the broad scope of possible embodiments.

FIG. 4 illustrates the components of a computer device 400 that may implement a noise suppressing heat exchanger, such as one of heat exchanger 100 (FIGS. 1A-1C), heat exchanger 200 (FIGS. 2A and 2B), or heat exchanger 300 (FIG. 3). Computer device 400 includes a heat-generating component 402, which may be a general purpose processor, a System on a Chip (SoC), a graphics processing unit (GPU), memory controller, transistor, or any other component expected to generate heat during use sufficient to require dissipation via a heat exchanger. Component 402 is contacted by the cold plate of a heat pipe 404, which is configured to conduct heat away from component 402 to a hot plate on its distal end. Heat pipe 404 may be implemented using any known technique. The hot plate of heat pipe 404 in turn contacts the cold plate of a heat exchanger 406, which absorbs heat from the heat pipe 404 for dissipation. Heat exchanger 406 may be an implementation of heat exchanger 100, heat exchanger 200, heat exchanger 300, or another embodiment of a noise-suppressing heat exchanger. Located adjacent to heat exchanger 406 is a fan 408, which is configured to force air through the side of heat exchanger 406, through its air channels, where it then exits out the distal side of heat exchanger 406 after having absorbed heat from the fins forming the air channels.

Computer device 400 may, in some embodiments, have multiple heat exchangers and multiple fans, where one or more, or all of the heat exchangers are configured for noise suppression. Other embodiments may have multiple fans arranged to pass air through a single heat exchanger. As discussed above, in still other embodiments, the heat exchanger and fan may be arranged to directly contact the component 402, rather than requiring a heat pipe to conduct heat to a distally located heat exchanger 406.

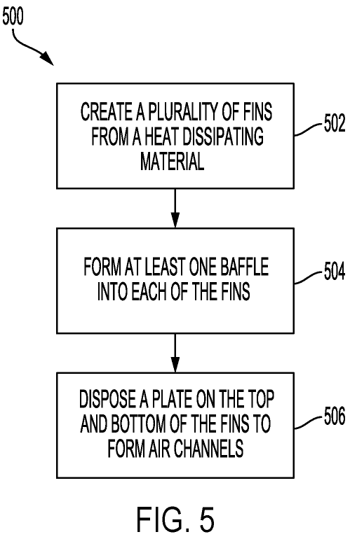

FIG. 5 illustrates the operations of a method 500 for creating a noise-suppressing heat exchanger, such as heat exchanger 100 (FIGS. 1A-1C), heat exchanger 200 (FIGS. 2A and 2B), or heat exchanger 300 (FIG. 3). The operations of method 500 may be carried out in order or out of order, depending upon the needs of a specific implementation. Some operations may be omitted and/or other operations may be added, depending upon the specifics of a given embodiment.

In operation 502, a plurality of fins are created from a heat dissipating material, such as copper, aluminum, an alloy, or some other suitable material or combination of materials. The thickness of the fins may depend on the amount of heat to be dissipated, as the thickness will impact the overall thermal mass of the resulting heat exchanger.

In operation 504, at least one baffle is formed into each of at least a subset of the fins. As discussed above with respect to FIG. 1A - 3, all or some of the plurality of fins may be formed with baffles. The baffles may be formed into the walls of the fins, such as baffles 110 of heat exchanger 100, or the fins themselves may be shaped into patterns, similar to the baffles of heat exchangers 200 and 300. The baffles may be formed to create obstructions to cause air flow to be slowed or redirected as it passes over the baffles, and may include angles or facets to reflect sound energy away from the path of air flow.

In operation 506, each of the fins are disposed between and attached to top and bottom plates. In embodiments, at least one, or both, of the top and bottom plates are formed from heat conducting material to transfer heat to the fins for dissipation. So disposed, air channels are formed between the fins. The air channels are shaped by the presence of the baffles so that air flow is slowed as compared to a straight-sided (no baffles) air channel, which serves to reduce noise, and absorb and reflect sound energy.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

### EXAMPLES

The following examples pertain to further embodiments.

Example 1 is a heat exchanger for an apparatus, comprising a bottom plate; a top plate; and a plurality of heat dissipating fins extending between the top and bottom plates that form a plurality of air channels; wherein at least one of the top plate and bottom plate comprises a heat conducting material, the plurality of heat dissipating fins receive heat from the top or bottom plates, and individuals of at least a subset of the plurality of fins include a baffle that protrudes into an individual of the plurality of air channels.

Example 2 includes the subject matter of example 1, or some other example herein, wherein all of the fins of the plurality of heat dissipating fins include at least one baffle.

Example 3 includes the subject matter of example 1, or some other example herein, wherein a subset of the plurality of fins do not have a baffle.

Example 4 includes the subject matter of example 3, or some other example herein, wherein the subset of the plurality of fins that do not have a baffle are interleaved with the subset of the plurality of fins that include a baffle.

Example 5 includes the subject matter of any of examples 1-4, or some other example herein, wherein the baffles increase the surface area of the subset of the plurality of fins.

Example 6 includes the subject matter of any of examples 1-5, or some other example herein, wherein individuals of the baffles comprise a rounded rectangular depression that protrudes from a plane defined by the baffle’s fin.

Example 7 includes the subject matter of any of examples 1-6, or some other example herein, wherein individuals of the baffles comprise the baffle’s fin formed into a sinusoidal pattern.

Example 8 includes the subject matter of any of examples 1-7, or some other example herein, wherein individuals of the baffles comprise the baffle’s fin formed into a plurality of alternating angles.

Example 9 includes the subject matter of any of examples 1-8, or some other example herein, wherein the heat exchanger is formed from copper or aluminum.

Example 10 is a method, comprising creating, from a heat dissipating material, a plurality of heat dissipating fins; forming a baffle into individuals of a subset of the plurality of fins; and forming a plurality of air channels by disposing the plurality of fins between a top plate and a bottom plate, at least one of the top plate and bottom plate comprised of a heat conducting material, wherein individuals of the baffles protrude into corresponding individuals of the plurality of air channels.

Example 11 includes the subject matter of example 10, or some other example herein, wherein the subset of the plurality of fins comprises all of the plurality of fins.

Example 12 includes the subject matter of example 10, or some other example herein, wherein a subset of the plurality of fins do not have a baffle.

Example 13 includes the subject matter of example 12, or some other example herein, wherein the subset of the plurality of fins that do not have a baffle are interleaved with the subset of the plurality of fins that include a baffle.

Example 14 includes the subject matter of any of examples 10-13, or some other example herein, wherein forming a baffle into individuals of the subset of the plurality of fins comprises forming a rectangular depression from a plane defined by the baffle’s fin.

Example 15 includes the subject matter of any of examples 10-14, or some other example herein, wherein forming a baffle into individuals of the subset of the plurality of fins comprises forming the fin into a sinusoidal pattern.

Example 16 includes the subject matter of any of examples 10-15, or some other example herein, wherein forming a baffle into individuals of the subset of the plurality of fins comprises forming the fin into a plurality of alternating angles.

Example 17 is a computer device, comprising a processor; a heat exchanger adapted to dissipate heat from the processor; and a fan disposed to pass air through the heat exchanger; wherein the heat exchanger comprises a top plate and a bottom plate, at least one of the top plate or bottom plate being heat conducting, and a plurality of heat dissipating fins extending between the top and bottom plates to form a plurality of air channels, the plurality of heat dissipating fins disposed to receive heat from the top or bottom plates, and individuals of at least a subset of the plurality of fins include a baffle that protrudes into an individual of the plurality of air channels.

Example 18 includes the subject matter of example 17,or some other example herein, further comprising a heat pipe in contact with the processor and the heat exchanger, and adapted to conduct heat generated by the processor to the heat exchanger.

Example 19 includes the subject matter of example 17 or 18, or some other example herein, wherein the computer device is a laptop computer.

Example 20 includes the subject matter of example 17 or 18, or some other example herein, wherein the computer device is a mobile device.

What is claimed is:

1. A heat exchanger for an apparatus, comprising:
a bottom plate;
a top plate; and
a plurality of heat dissipating fins extending between the top and bottom plates that form a plurality of air channels;
wherein at least one of the top plate and bottom plate comprises a heat conducting material, the plurality of heat dissipating fins receive heat from the top or bottom plates, and individuals of at least a subset of the plurality of fins include a baffle that protrudes into an individual of the plurality of air channels.

2. The heat exchanger of claim 1, wherein all of the fins of the plurality of heat dissipating fins include at least one baffle.

3. The heat exchanger of claim 1, wherein a subset of the plurality of fins do not have a baffle.

4. The heat exchanger of claim 3, wherein the subset of the plurality of fins that do not have a baffle are interleaved with the subset of the plurality of fins that include a baffle.

5. The heat exchanger of claim 1, wherein the baffles increase the surface area of the subset of the plurality of fins.

6. The heat exchanger of claim 1, wherein individuals of the baffles comprise a rounded rectangular depression that protrudes from a plane defined by the baffle’s fin.

7. The heat exchanger of claim 1, wherein individuals of the baffles comprise the baffle’s fin formed into a sinusoidal pattern.

8. The heat exchanger of claim 1, wherein individuals of the baffles comprise the baffle’s fin formed into a plurality of alternating angles.

9. The heat exchanger of claim 1, wherein the heat exchanger is formed from copper or aluminum.

10. A method, comprising:
creating, from a heat dissipating material, a plurality of heat dissipating fins;
forming a baffle into individuals of a subset of the plurality of fins; and
forming a plurality of air channels by disposing the plurality of fins between a top plate and a bottom plate, at least one of the top plate and bottom plate comprised of a heat conducting material,
wherein individuals of the baffles protrude into corresponding individuals of the plurality of air channels.

11. The method of claim 10, wherein the subset of the plurality of fins comprises all of the plurality of fins.

12. The method of claim 10, wherein a subset of the plurality of fins do not have a baffle.

13. The method of claim 12, wherein the subset of the plurality of fins that do not have a baffle are interleaved with the subset of the plurality of fins that include a baffle.

14. The method of claim 10, wherein forming a baffle into individuals of the subset of the plurality of fins comprises forming a rectangular depression from a plane defined by the baffle’s fin.

15. The method of claim 10, wherein forming a baffle into individuals of the subset of the plurality of fins comprises forming the fin into a sinusoidal pattern.

16. The method of claim 10, wherein forming a baffle into individuals of the subset of the plurality of fins comprises forming the fin into a plurality of alternating angles.

17. A computer device, comprising:
a processor;
a heat exchanger adapted to dissipate heat from the processor; and
a fan disposed to pass air through the heat exchanger;
wherein the heat exchanger comprises:
a top plate and a bottom plate, at least one of the top plate or bottom plate being heat conducting, and
a plurality of heat dissipating fins extending between the top and bottom plates to form a plurality of air channels, the plurality of heat dissipating fins disposed to receive heat from the top or bottom plates, and individuals of at least a subset of the plurality of fins include a baffle that protrudes into an individual of the plurality of air channels.

18. The computer device of claim 17, further comprising a heat pipe in contact with the processor and the heat exchanger, and adapted to conduct heat generated by the processor to the heat exchanger.

19. The computer device of claim 17, wherein the computer device is a laptop computer.

20. The computer device of claim 17, wherein the computer device is a mobile device.
